(19) United States
(12) Patent Application Publication
(10) Pub. No.: US 2025/0299987 A1
(43) Pub. Date: Sep. 25, 2025

(54) JUNCTION PASSAGE CONTROL SYSTEM BASED ON LOCATION OF VEHICLE AND CONTROLLING METHOD USING THE SAME

(71) Applicant: Cantops co.ltd, Suwon-si Gyeonggi-do (KR)

(72) Inventors: Hak Seo OH, Yongin-si Gyeonggi-do (KR); Youl Kwon SUNG, Hwaseong-si Gyeonggi-do (KR); Sung Ik KIM, Hwaseong-si Gyeonggi-do (KR); Deok Ha LEE, Osan-si Gyeonggi-do (KR); Seong Min HWANG, Suwon-si Gyeonggi-do (KR); Won Jai LEE, Suwon-si Gyeonggi-do (KR); Sung Hyuk YOUN, Incheon (KR); Se Hun LEE, Suwon-si Gyeonggi-do (KR)

(73) Assignee: Cantops co.ltd, Suwon-si Gyeonggi-do (KR)

(21) Appl. No.: 19/083,716

(22) Filed: Mar. 19, 2025

(30) Foreign Application Priority Data
Mar. 25, 2024 (KR) 10-2024-0040312
Nov. 27, 2024 (KR) 10-2024-0172478

(51) Int. Cl. H01L 21/67; G05D 1/226; G05D 1/693; H01L 21/677

(52) U.S. Cl. CPC H01L 21/67265; G05D 1/226; G05D 1/693; H01L 21/677

(57) ABSTRACT

The present disclosure relates to a junction area passage control system based on a location of moving body using wireless communication on a rail, the rail including a junction section formed by merging of two or more rails. The junction area passage control system includes a vehicle control device installed on each of a plurality of moving bodies, and including a communication module for wireless communication between the moving bodies and a control unit configured to control driving of a corresponding moving body, and a junction section-side central control device including a communication module for wireless communication with the vehicle control device and configured to receive information about locations and movement states of the plurality of moving bodies in the junction section, monitor driving situations of the plurality of moving bodies traveling in the junction section, and determine entry priority of moving bodies.

### CROSS REFERENCE TO RELATED APPLICATIONS

The present application claims priority of Korean Patent Application No. 10-2024-0040312 filed on Mar. 25, 2024 and Korean Patent Application No. 10-2024-0172478 filed on Nov. 27, 2024, the entire contents of which is incorporated herein for all purposes by this reference.

### BACKGROUND OF THE DISCLOSURE

### Field of the Disclosure

The present disclosure relates to a junction area passage control system based on the location of a moving body using wireless communication (RF communication) and a control method using the junction area passage control system.

### Description of the Related Art

An Overhead Hoist Transport (OHT) system for logistics (wafer) transportation in semiconductor manufacturing process lines is operated such that an OHT Control System (OCS) (higher-level system) issues a transport command to an OHT and such that the OHT travels along rails to the final destination of the transport command and delivers semiconductor wafers through a handoff process with production equipment.

A logistics system in semiconductor manufacture process lines repeatedly performs the above-described handoff process. In order to improve logistics productivity, a plurality of OHTs may pass through junction and branching sections while traveling along the rails. An OHT, the driving path of which is set by a command from the OCS, cannot know driving path information of another OHT, and thus there may occur the case where OHTs traveling along different rails intend to simultaneously pass through a junction section.

### Document of Related Art

### Patent Document

(Patent Document 1) Korean Patent Application Publication No. 10-2018-0010764 (Jan. 31, 2018)

### SUMMARY OF THE DISCLOSURE

The present disclosure has been made in an effort to provide a junction area passage control system based on the location of a moving body using wireless communication and a control method using the junction area passage control system, which can provide a simple wireless communication configuration that enables driving control and interlock control in a junction section, without requiring a complex setup such as installing power line communication lines for communication on the tracks of a junction section.

To achieve the above-mentioned object, the present disclosure provides a junction area passage control system based on a location of moving body using wireless communication on a rail, the rail including a junction section formed by merging of two or more rails, the junction area passage control system including a vehicle control device installed on each of a plurality of moving bodies, and including a communication module for wireless communication between the moving bodies and a control unit configured to control driving of a corresponding moving body; and a junction section-side central control device including a communication module configured to perform wireless communication with the vehicle control device, the junction section-side central control device being configured to receive information about locations and movement states of the plurality of moving bodies in the junction section, monitor driving situations of the plurality of moving bodies traveling in the junction section, and determine entry priority of the plurality of moving bodies, wherein, in a normal state, control of the corresponding moving body by the vehicle control device is performed, and in an emergency state, control by the junction section-side central control device is prioritized over the control by the vehicle control device, and wherein the emergency state is a case where the moving bodies on the respective rails simultaneously enter a junction driving zone set in the junction section.

In addition, the junction section may include a first control section in which junction control communication initiation of transmitting and receiving a junction section communication signal and verification for the communication module of the vehicle control device are performed, a second control section that follows the first control section and in which location-based movement control of the corresponding moving body is performed, and a third control section that follows the second control section and corresponds to the junction driving zone.

In addition, the communication module of the vehicle control device may include a first communication unit configured to receive a junction section communication signal of a communication module of another moving body on an identical rail among rails in the junction section and transmit a junction section communication signal to a communication module of an additional moving body on a rail different from the corresponding rail; a second communication unit configured to receive the junction section communication signal of the communication module of the additional moving body on the different rail, receive the junction section communication signal of the first communication unit, and then determine a normal communication state of the communication module of the vehicle control device; a third communication unit configured to receive the junction section communication signal of the communication module of the additional moving body on the different rail; and a fourth communication unit configured to enable communication with the communication module of the junction section-side central control device.

In addition, the junction area passage control system may further include a track indication device attached to a rail body of each of the rails, wherein each of the moving bodies further includes a movement distance measurement module configured to measure a rail movement distance of a corresponding moving body, and an indication device recognition module capable of recognizing the track indication device, the track indication device includes a first track indication device, the movement distance measurement module includes an optical sensor or a camera module, the first track indication device is arranged at a start point of the first control section, when the indication device recognition module of the moving body recognizes the first track indication device, the moving body is determined to have entered the first control section, and the track indication device is an optical tag that is capable of being optically recognized.

In addition, the track indication device may further include a second track indication device and a third track indication device arranged at locations different from that of the first track indication device, when the moving body recognizes the second track indication device, the moving body is determined to have entered the second control section, and when the moving body recognizes the third track indication device, the moving body is determined to have entered the third control section.

In addition, when the moving body is determined to have entered the first control section to perform verification for the communication module in the first control section and then the verification for the communication module is completed, location-based movement control in the second control section may be performed, and when the moving body is moved by a predetermined distance in a state in which the moving body has entered the second control section, the moving body may be determined to have entered the third control section.

In addition, when a signal received through the communication module of the moving body that has entered the second control section of the junction section is (1) a junction section communication signal corresponding to a driving state of another moving body located on a rail identical to the rail on which the moving body is traveling, or (2) a junction section communication signal corresponding to verification for a communication module of an additional moving body on the identical rail or a rail different from the rail, the moving body may continue driving thereof, and when the signal received through the communication module of the moving body that has entered the second control section of the junction section is a junction section communication signal corresponding to a driving state of the additional moving body located on the rail different from the rail on which the moving body is traveling, the moving body may stop driving thereof by transmitting an interlock signal, and when a signal received through the communication module of the moving body that has entered the third control section of the junction section is (1) a junction section communication signal corresponding to a driving state of additional moving bodies on the rail different from the rail on which the moving body is traveling, all of the moving body on the rail and the additional moving bodies on the different rail may stop driving thereof by transmitting interlock signals, wherein at least one of the moving body and additional moving bodies transmits a junction section communication signal corresponding to a stopped state to the junction section-side central control device.

In addition, when the junction section communication signal corresponding to the stopped state is received, the junction section-side central control device may be configured to select, as a prioritized passage moving body, a moving body with a shorter distance to a passage point of the junction area or with a shorter passage time to pass through the passage point from among moving bodies that have entered the third control section, and to transmit a junction section-side central control signal for releasing an interlock signal for the prioritized passage moving body to resume driving of the prioritized passage moving body. In addition, transmission speed of the junction section communication signal transmitted from each moving body may increase in an order in which the moving body is located in the first control section, the second control section, and the third control section, and transmission of the junction section communication signal may be terminated when the moving body has passed through the junction area.

In addition, transmission speed of the junction section communication signal transmitted from each moving body may increase as a speed of the moving body becomes higher.

In addition, the junction section communication signal may further include an operational state indicating a state in which each moving body performs a loading/unloading operation, a loading/unloading platform in which the moving body performs the loading/unloading operation may be arranged in the third control section of at least one of a plurality of rails, and when the moving body performs the loading/unloading operation in the loading/unloading platform, the vehicle control device of the moving body may transmit a junction section communication signal corresponding to the operational state, and a vehicle control device of an additional moving body traveling on a rail different from that of the moving body may receive the junction section communication signal corresponding to the operational state and allow the additional moving body to continue driving in the third control section.

In addition, when the loading/unloading operation of the moving body is terminated in the junction section, the vehicle control device of the moving body on which the loading/unloading operation is terminated may be configured to determine whether a junction section communication signal corresponding to a driving state of the vehicle control device of the additional moving body traveling on the different rail is received, and to transmit the junction section communication signal corresponding to the driving state and resume driving of the corresponding moving body when the junction section communication signal corresponding to the driving state is not received from the additional moving body.

In addition, the junction section-side central control device may monitor the locations and the movement states of the plurality of moving bodies in the junction section based on junction section communication signals transmitted from the plurality of moving bodies, select a moving body to perform prioritized passage in the third control section from among the plurality of moving bodies, and transmit a junction section communication signal for allowing the selected moving body to perform prioritized passage.

In addition, the junction section-side central control device may control moving bodies located in the junction area, other than the moving body to perform prioritized passage, to prevent the moving bodies from entering the third control section.

In addition, when one or more additional moving bodies are located in a junction area including rails identical to and different from that of the moving body to perform prioritized passage, the junction section-side central control device may calculate (1) a sequential prioritized passage time required for moving bodies located on different rails to sequentially perform prioritized passage, and (2) a clustered prioritized passage time required for moving bodies located on the identical rail on which the moving body to perform the prioritized passage is located to consecutively perform prioritized passage, when the clustered prioritized passage time is shorter than the sequential prioritized passage time, clustered prioritized passage control may be performed such that the plurality of moving bodies on the identical rail on which the moving body to perform prioritized passage is located are selected as a prioritized passage cluster to perform prioritized passage, moving bodies on a remaining rail, other than the moving bodies on which the clustered prioritized passage control is performed, may be controlled to prevent the moving bodies from entering the third control section, and the moving bodies included in the prioritized passage cluster may be within a junction communication range between the moving bodies and the junction section-side central control device, wherein the junction communication range is equal to or greater than the junction area of the rail.

To achieve the above-mentioned object, the present disclosure provides a junction area passage control method based on a location of a moving body using wireless communication on a rail including a first rail, a second rail forming a route different from that of the first rail, and a junction rail formed by merging of the first rail and the second rail, wherein the location-based junction area passage control system includes a vehicle control device installed on each of a plurality of moving bodies and including a communication module for wireless communication between the moving bodies and a control unit configured to control driving of each moving body, the junction area passage control method including a moving body junction area entry determination step of determining whether a moving body traveling on any one of the first rail and the second rail has entered a junction area in which the first rail and the second rail are merged; a junction control communication mode initiation step of, when the moving body has entered the junction area, initiating a junction control communication mode of the moving body in which a junction area communication signal is transmitted and received; a first junction section communication signal reception/non-reception determination step of determining whether a junction section communication signal of an additional moving body is received by the moving body in which the junction control communication mode has been initiated; a communication module verification step of checking a normal operation state of a communication module of the moving body on which the junction control communication mode has been initiated; and when the communication module verification step is terminated, a location-based driving state signal transmission step of transmitting, by the moving body, a junction section communication signal corresponding to a driving state.

In addition, the junction area passage control method may further include a second junction section communication signal reception/non-reception determination step of determining whether the junction section communication signal of the additional moving body is received by the moving body on which verification for a communication module is terminated; and a third junction section communication signal reception/non-reception determination step of determining whether the junction section communication signal of the additional moving body is received by the moving body in which transmission of the junction section communication signal corresponding to the driving state has been initiated.

In the first junction section communication signal reception/non-reception determination step, the second junction section communication signal reception/non-reception determination step, and the third junction section communication signal reception/non-reception determination step, when the junction section communication signal of the additional moving body is received, a drivability determination step of determining whether driving is possible may be performed, in the drivability determination step, driving of the moving body may continue either in a state in which the additional moving body is located on the identical rail or when the verification for the communication module is performed on the additional moving body, based on the junction section communication signal of the additional moving body, and in the drivability determination step, driving of the moving body may stop when it is determined, based on the junction section communication signal of the additional moving body, that the additional moving body is traveling while being located on the different rail.

In addition, the junction area passage control method may further include a step of determining whether the moving body has entered a danger zone of the junction area in a state in which the driving of the moving body stops, and a central control device flow control waiting step of, when the moving body has entered the danger zone, allowing the moving body to follow flow control of the junction section-side central control device.

In addition, in the central control device flow control waiting step, a vehicle control device of the moving body located in the danger zone may transmit a junction section communication signal corresponding to a stopped state.

In addition, the central control device flow control waiting step may include a simultaneously entering vehicle information reception step of allowing the junction section-side central control device to receive junction section communication signals of moving bodies simultaneously entering the danger zone; and a prioritized passage moving body selectability determination step of allowing the junction section-side central control device to select a moving body to perform prioritized passage through the danger zone from among the simultaneously entering moving bodies, wherein, in the prioritized passage moving body selectability determination step, the junction section-side central control device selects, as a prioritized passage moving body, a moving body with a shorter distance to a passage point of the junction area or a shorter passage time to the passage point from among moving bodies that have simultaneously entered the danger zone, and wherein the prioritized passage moving body selectability determination step includes, when the junction section-side central control device cannot select the moving body to perform prioritized passage, a higher-level control device alarm step of allowing the junction section-side central control device to transfer an alarm to a higher-level control device.

In addition, in each of the first rail and the second rail, a junction control section may be established, and the junction control section may include a first control section in which junction control communication initiation of transmitting and receiving a junction section communication signal and verification for the communication module of the vehicle control device are performed, a second control section that follows the first control section and in which location-based movement control of the corresponding moving body is performed, and a third control section that follows the second control section and corresponds to a junction driving zone.

In addition, transmission speed of the junction section communication signal transmitted from each moving body may increase in an order in which the moving body is located in the first control section, the second control section, and the third control section, and transmission of the junction section communication signal may be terminated when the moving body has passed through the junction area.

In addition, transmission speed of the junction section communication signal transmitted from each moving body may increase as a speed of the moving body becomes higher.

In addition, the communication module of the vehicle control device may include a plurality of communication units, and in the communication module verification step, in a state in which a first communication unit, among the communication units of the moving body, transmits a junction section communication signal corresponding to a communication module verification state, (1) when a second communication unit different from the first communication unit, among the communication units of a moving body identical to the moving body, receives the junction section communication signal transmitted from the first communication unit, the communication module of the moving body may be determined to be in a normal state, and (2) when the second communication unit of the identical moving body cannot receive the junction section communication signal transmitted from the first communication unit, the communication module may be determined to be in an abnormal state, and when the communication module is determined to be in an abnormal state, the vehicle control device may stop by transmitting an interlock signal, and transfer a communication module error signal indicating the abnormal state of the communication module to a junction section-side central control device.

To achieve the above-mentioned object, the present disclosure provides a junction area passage control system based on a location of a moving body using wireless communication on a rail, the rail including a junction section formed by merging of two or more rails, the junction area passage control system including a vehicle control device installed on each of moving bodies and including a communication module for wireless communication between the moving bodies and a control unit configured to control driving of a corresponding moving body, wherein the moving bodies are provided in plurality, and wherein the vehicle control device installed on any one of the moving bodies transmits and receives a junction section communication signal to/from a vehicle control device installed on another moving body, and is configured to set entry priority of the moving bodies into a danger zone based on mutual locations of the moving bodies.

In addition, when at least two of the moving bodies simultaneously enter the danger zone, the moving bodies that simultaneously enter the danger zone may stop while transmitting a junction section communication signal corresponding to a stopped state, the stopped moving bodies may choose a representative moving body for selecting a prioritized passage moving body in the danger zone, and the representative moving body may receive junction section communication signals of other moving bodies to select a prioritized passage moving body, and when the representative moving body selects the prioritized passage moving body, the representative moving body may select the prioritized passage moving body based on distances to a point at which the rails are merged.

### BRIEF DESCRIPTION OF THE DRAWINGS

FIG. 1 is a diagram illustrating a location-based junction area passage control system according to an embodiment of the present disclosure.

FIGS. 2 and 3 are diagrams illustrating a process of controlling junction and passage of a moving body using the location-based junction area passage control system of FIG. 1.

FIG. 4 is a diagram illustrating a process in which the vehicle control device of a moving body communicates with a junction section-side central control device in the location-based junction area passage control system of FIG. 1.

FIG. 5 is a diagram illustrating a process in which a vehicle control device transmits a driving state signal based on location information while a moving body passes through a junction area in the location-based junction area passage control system of FIG. 1.

FIG. 6 is a flowchart illustrating a control process by the vehicle control device of the location-based junction area passage control system of FIG. 1.

FIG. 7 is a flowchart illustrating a control process by a junction section-side central control device when simultaneous entry occurs in a danger zone in the location-based junction area passage control system of FIG. 1.

FIGS. 8 and 9 are diagrams illustrating a process of controlling junction and passage of a moving body in a location-based junction area passage control system according to another embodiment of the present disclosure.

FIG. 10 is a diagram illustrating a process of controlling junction and passage of a moving body in a location-based junction area passage control system according to a further embodiment of the present disclosure.

FIG. 11 is a diagram illustrating a process of controlling junction and passage of a moving body in a location-based junction area passage control system according to yet another embodiment of the present disclosure.

FIG. 12 is a diagram illustrating a location-based junction area passage control system according to still another embodiment of the present disclosure.

### DETAILED DESCRIPTION OF THE DISCLOSURE

The advantages and features of the present disclosure, as well as methods for achieving them, will become apparent by referring to embodiments described in detail below in conjunction with the accompanying drawings. However, the present disclosure is not limited to the embodiments disclosed herein and can be implemented in various other forms. The embodiments of the present disclosure are intended to fully describe the present disclosure, and to fully inform those skilled in the art, to which the present disclosure pertains, of the scope of the disclosure. The present disclosure is defined only by the scope of the accompanying claims.

Although terms such as “first” and “second” are used to describe various components, it is apparent that these terms are not intended to limit the components. These terms are merely used to distinguish one component from another. Therefore, it is apparent that a first component described below may be a second component within the technical scope of the present disclosure.

Throughout the specification, the same reference numerals refer to the same components.

The features of various embodiments of the present disclosure may be combined or integrated either partially or entirely. As will be readily understood by those skilled in the art, various technical interconnections and operations are possible. Respective embodiments may be implemented independently or in conjunction with each other in a relational context.

Meanwhile, any potential effects that can be expected based on the technical features of the present disclosure but are not explicitly mentioned in the specification of the present disclosure should be considered as described herein. The embodiments are provided to more fully explain the present disclosure to those skilled in the art. The contents shown in the drawings may be exaggerated and represented compared to the actual implementation of the disclosure. Detailed descriptions of configurations which have been deemed to make the gist of the present disclosure unnecessarily obscure will be omitted or briefly made.

Hereinafter, embodiments of the present disclosure will be described in detail with reference to the attached drawings.

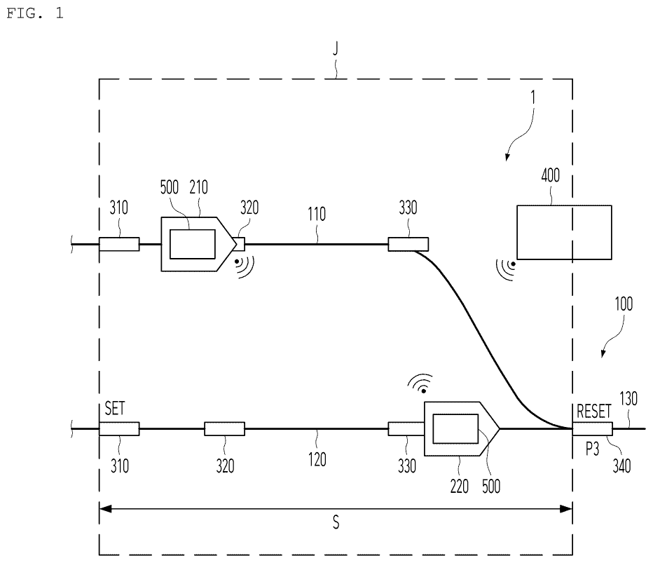

FIG. 1 is a diagram illustrating a location-based junction area passage control system according to an embodiment of the present disclosure.

Referring to FIG. 1, a junction area (junction) passage control system 1 based on the location of a moving body (e.g., a vehicle) using wireless communication according to the present embodiment allows moving bodies 210 and 220 on a rail 100, which includes a first rail 110, a second rail 120 forming a route different from that of the first rail 110, and a junction rail 130 formed by the merging of the first rail 110 and the second rail 120, to stably travel from the first rail 110 and the second rail 120 to the junction rail 130 without interfering with each other.

In detail, the junction area passage control system 1 according to the present embodiment may include a junction section-side central control device 400 and vehicle control devices 500. The junction section-side central control device 400 receives junction section communication signals indicating the locations and movement states of a plurality of moving bodies 210 and 220 on the rail 100, and determines the entry priorities of the plurality of moving bodies 210 and 220 in a junction area (junction) J in which the first rail 110 and the second rail 120 of the rail 100 are merged. The vehicle control devices 500 are installed in the moving bodies 210 and 220, respectively, and are configured to transmit or receive the junction section communication signals and control the moving bodies 210 and 220 based on junction section communication signals indicating the locations and movement states of other moving bodies 210 and 220.

In the junction area passage control system 1 according to the present embodiment, in a normal state, the control of the moving bodies 210 and 220 is performed by the vehicle control devices 500. In an emergency state, control by the junction section-side central control device 400 is prioritized over the control by the vehicle control devices 500. Here, the emergency state may refer to a situation where at least two of the moving bodies enter a danger zone set within a connecting zone of the junction area J, in which the first rail and the second rail are connected, and the normal state may refer to any state other than the emergency state.

Meanwhile, in the present embodiment, communication between the moving bodies 210 and 220 and between the moving bodies 210 and 220 and the junction section-side central control device 400 is based on wireless communication. The wireless communication may be used together with one or more types of Radio Frequency (RF), Frequency-Division Multiplexing (FDM), Orthogonal FDM (OFDM), Single Carrier Frequency-Division Multiple Access (SC-FDMA), Time-Division Multiplexing (TDM), Time-Division Multiple Access (TDMA), Extended TDMA (E-TDMA), General Packet Radio Service (GPRS), Enhanced GPRS, Code-Division Multiple Access (CDMA), Wideband CDMA (WCDMA), CDMA 2000, single carrier CDMA, multi-carrier CDMA, Multi-Carrier Modulation (MCM), Discrete Multi-Tone (DMT), Bluetooth®, Global Positioning System (GPS), Wireless Fidelity (Wi-Fi), Wi-Max, ZigBee™, Ultra-Wideband (UWB), Global System for Mobile Communication (GSM), second generation (2G), 2.5G, 3G, 3.5G, 4G, and Fifth Generation (5G) mobile networks, 3GPP, Long Term Evolution (LTE) cellular system, LTE-advanced cellular system, High-Speed Downlink Packet Access (HSDPA), High-Speed Uplink Packet Access (HSUPA), High-Speed Packet Access (HSPA), HSPA+, Single Carrier Radio Transmission Technology (1×RTT), Evolution-Data Optimized (EV-DO), and Enhanced Data rates for GSM Evolution (EDGE). Other embodiments may be used in various other devices, systems and/or networks.

The junction area passage control system 1 according to the present embodiment may detect the locations of the main bodies 210 and 220 on the rail 100. For this, the rail 100 may include a rail body and a plurality of tag units 310, 320, and 330 arranged on the rail body. Each of the moving bodies 210 and 220 may further include a tag sensing module (not illustrated) for sensing the tag units 310, 320, and 330, and the vehicle control device 500 may recognize the locations of the moving bodies 210 and 220 on the rail 100 based on the tag information of the tag units 310, 320, and 330. In an example, the tag units 310, 320, and 330 may include optical tags, such as barcodes or QR codes, or communication tags, such as RFID. The tag sensing module may include an optical sensor or a communication module capable of recognizing the tag units 310, 320, and 330. Here, the tag units 310, 320, and 330 may be referred to as track indication devices.

Meanwhile, on each of the first rail 110 and the second rail 120, a plurality of junction control sections S may be established. The junction control sections S may include a first control section S1 in which a junction control communication mode in the junction area J is initiated, a second control section S2 that follows the first control section S1 and in which verification for the communication module (not illustrated) of the corresponding vehicle control device 500 is executed and the junction section communication signal of the moving body 210 or 220 is transmitted, and a third control section S3 that follows the second control section S2 and corresponds to the danger zone.

In an example, in the case based on the points of the tag units, when each of the moving bodies 210 and 220 travels and senses the first tag unit 310, the vehicle control device 500 of the corresponding moving body 210 or 220 recognizes that the corresponding moving body 210 or 220 has entered the first control section S1. Similarly, when the moving bodies 210 and 220 sense the second tag unit 320 and the third tag unit 330, respectively, while traveling, the vehicle control devices 500 of the moving bodies 210 and 220 recognizes that the corresponding moving bodes 210 and 220 have entered the second control section S2 and the third control section S3, respectively. Further, when each of the moving bodies 210 and 220 senses a fourth tag unit 340 while traveling, the vehicle control device 500 of the corresponding moving body 210 or 220 recognizes that the corresponding moving body 210 or 220 has passed through the junction area J, and terminates the transmission/reception of the junction section communication signals.

At least one tag unit may be further installed between the first tag unit 310 and the second tag unit 320, between the second tag unit 320 and the third tag unit 330, and between the third tag unit 330 and the fourth tag unit 340, and the tag units may be arranged at equidistant intervals.

Here, the number of tag unit(s) 310 installed in the first control section S1 may be smaller than the number of tag units 320 installed in the second control section S2.

That is, the actual length of the first control section S1 may be formed to be smaller than the actual length of the second control section S2.

Meanwhile, a configuration in which the moving bodies 210 and 220 performs operations in the control sections S1, S2, and S3 in a time-series manner after entering the junction control section S based only on a single tag unit is also included in the configuration of the present disclosure.

In detail, when a moving body on any one rail recognizes the first tag unit 310, the moving body is determined to have entered the first control section S1 of the junction control section S, and then performs verification for the communication module. Then, when the verification for the communication module of the moving body is completed, location-based movement control in the second control section is performed. Further, when the location-based movement control in the second control section is performed and the moving body is moved by a predetermined distance, the moving body is determined to have entered the third control section.

In the present embodiment, although the moving bodies 210 and 220 are described as having entered the junction control point S based on the tag units, a configuration in which the moving bodies 210 and 220 are determined to have entered the junction control section S based on a cumulative distance accumulated while moving, or a configuration in which an absolute position indication unit provided on the rail is recognized by the moving bodies 210 and 220 and then the moving bodies 210 and 220 are determined to have entered the junction control section S, may also be included in the embodiment of the present disclosure.

Here, each moving body performs the location-based movement control based on the location information of the moving body. The location information may include the absolute position information of the moving body sensed by the tag units, the movement distance by which the corresponding moving body is moved from a preset point, and information about the distance to another preset point (e.g., a danger zone or a collision zone).

Meanwhile, each junction section communication signal may include communication signal type information, moving body information, driving rail information, and moving body driving distance information. Here, the communication signal type information refers to the operating state of the moving bodies 210 and 220, and states distinguished in the information include a driving state indicating the state in which the moving bodies 210 and 220 are moving, a stopped state indicating the state in which the moving bodies 210 and 220 have stopped due to simultaneous entry, and a communication module verification state used to check the communication state of the communication modules of the moving bodies 210 and 220.

In the junction area passage control system 1 according to the present embodiment, when the moving bodies 210 and 220 enter the first control section S1 of the junction control section S, the junction control communication mode is initiated. When the junction control communication mode is initiated, the operation of each of the vehicle control devices 500 of the moving bodies 210 and 220 is initiated. The corresponding vehicle control device 500 determines whether a junction section communication signal is received from the vehicle control device 500 of another moving body 210 or 220, and then determines whether to continue driving or to stop driving. Each of the moving bodies 210 and 220 performs a communication module verification operation on the communication module in the first control section S1.

Also, in the second control section S2, the moving body 210 or 220 performs a movement operation and a stop operation depending on whether a communication signal is received from the other moving body, the type of communication signal, and the location of the corresponding moving body 210 or 220. The control of the moving body 210 or 220 in the second control section S2 may be defined as the location-based movement control.

### Communication Module Verification Operation of Moving Body

When an unintended reception failure occurs due to a malfunction in the communication module of the moving body 210 or 220, the moving body 210 or 220, which recognizes that there is no preceding moving body 210 or 220, may enter a danger zone, i.e., the third control section S3, thus potentially leading to a collision. Therefore, the present embodiment provides a function allowing each of the moving bodies 210 and 220 to independently check whether there is a malfunction in the transmission/reception function of the communication module thereof, thus preventing collisions or other accidents between the moving bodies 210 and 220 caused by transmission/reception failures in the moving bodies 210 and 220.

More specifically, the communication module of the vehicle control device 500 includes a plurality of communication units. In case that the verification for the communication module is performed in the first control section, when, in the state in which a first communication unit among the communication units of the moving body 210 or 220 transmits the junction section communication signal corresponding to a communication module verification state, (1) a second communication unit different from the first communication unit among the communication units of the same moving body receives the junction section communication signal transmitted from the first communication unit, the communication module of the corresponding moving body 210 or 220 is determined to be in a normal state.

On the other hand, when the second communication unit of the same moving body 210 or 220 cannot receive the junction section communication signal transmitted from the first communication unit, the communication module is determined to be in an abnormal state. When the communication module is determined to be in the abnormal state, the vehicle control device 500 stops by transmitting an interlock signal, and transfers a communication module error signal indicating the abnormal state of the communication module to the junction section-side central control device 400.

Meanwhile, the communication module of each of the moving bodies 210 and 220 may further include a third communication unit (not illustrated) which receives the junction section communication signal transmitted from the other moving body 210 or 220, and a fourth communication unit (not illustrated) which communicates with the junction section-side central control device 400.

Hereinafter, a control process in the junction area J of the moving bodies 210 and 220 according to the present embodiment will be described in detail.

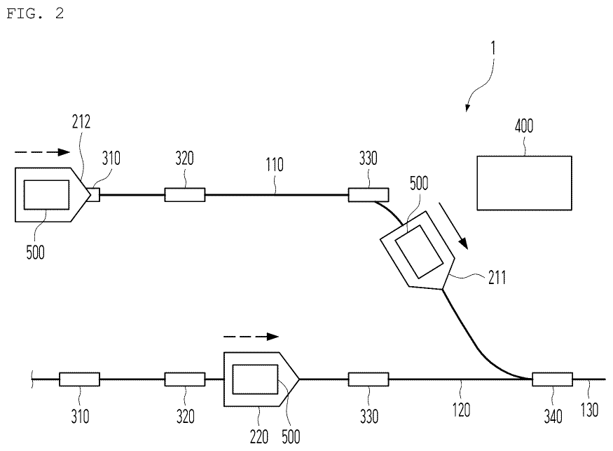

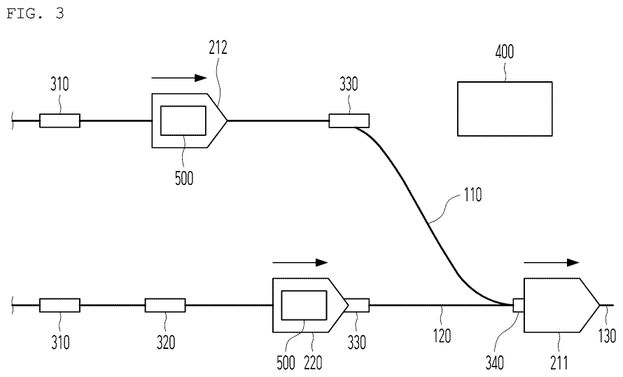

FIGS. 2 and 3 are diagrams illustrating a process of controlling junction and passage of a moving body using the location-based junction area passage control system of FIG. 1.

First, referring to FIG. 2, in the state in which the communication module of a first moving body 212, among a plurality of moving bodies 211, 212, and 220, receives a junction section communication signal transmitted from the communication module of the second moving body 220 that is another moving body, when the junction section communication signal of the second moving body 220 is a junction section communication signal corresponding to a communication module verification state, the vehicle control device 500 of the first moving body 212 allows the first moving body 212 to continue its driving.

That is, when the junction section communication signal received from the moving body 211, 212, or 220 is the junction section communication signal corresponding to the communication module verification state, the driving of the moving bodies 211, 212, and 220 does not affect a collision between the moving bodies 211, 212 and 220, with the result that the driving of the moving bodies 211, 212, and 220 is not influenced.

### Control Between Moving Bodies Traveling on Same Rail

Meanwhile, in the state in which the second moving body 212 receives the junction section communication signal of the first moving body 211, even in the case where the first moving body 211 is located on the same first rail 110 as the second moving body 212 and the junction section communication signal of the first moving body 211 is a junction section communication signal corresponding to a driving state, the vehicle control device 500 of the second moving body 212 allows the second moving body 212 to continue its driving.

Meanwhile, each of the moving bodies 211, 212, and 220 further includes a moving body distance measurement module for measuring the distance to another preceding moving body 211, 212, or 220. Further, when the second moving body 212 and the first moving body 211 are located on the same first rail 110, control related to whether to maintain the driving speed and the driving state of the second moving body 212 is performed based on distance measurement data of the first moving body 211, received in a wireless manner, and data measured by the distance measurement module of the second moving body 212.

### Control Between Moving Bodies Traveling on Different Rails

When the first moving body 220 on the second rail 120 receives a junction section communication signal corresponding to a driving state from the second moving body 211 located on the first rail 110, the vehicle control device 500 of the first moving body 220 stops the driving of the first moving body 220 based on the location of the first moving body 220. Here, the vehicle control device 500 of the first moving body 220 may transfer an interlock (driving stop) signal to a driving module (not illustrated) for controlling the movement of the first moving body 220.

Thereafter, when the second moving body 211 completely moves to the junction rail 130 after passing through the third control section S3, the transmission of the junction section communication signal of the second moving body 211 is terminated. Furthermore, the vehicle control device 500 of the first moving body 220 transmits the junction section communication signal corresponding to the driving state, and transfers a driving initiation signal to the driving module so as to allow the first moving body 220 to start driving.

Meanwhile, when the first moving body 220 is located in the third control section S3 of the second rail 120, and the second moving body 211 is located in the third control section S3 of the first rail 110, the vehicle control device 500 of each of the first moving body 220 and the second moving body 211 determines that the first moving body 220 and the second moving body 211 simultaneously enter the danger zone. Here, the vehicle control devices 500 of the first moving body 220 and the second moving body 211 stop the driving of the moving bodies 220 and 211 by transmitting interlock signals to the driving modules of the moving bodies 220 and 211, respectively. Here, the first moving body 220 and the second moving body 211 may notify other moving bodies and the junction section-side central control device 400 that the first moving body 220 and the second moving body 211 are currently interlocked in the junction control section S by transmitting junction section communication signals corresponding to the stopped state indicating driving stop.

When the first moving body 220 and the second moving body 211 are located in the third control section S3, and each of the first moving body 220 and the second moving body 211 receives the junction section communication signal corresponding to the stopped state (when the interlock signal is generated), the junction section-side central control device 400 selects, as a prioritized passage moving body, the one with a shorter distance to the passage point of the junction control section S or a shorter time to pass through the passage point, between the first moving body 220 and the second moving body 211. The junction section-side central control device 400 allows the driving of the prioritized passage moving body to initiate driving by transmitting a junction section-side central control signal that releases the interlock signal for the prioritized passage moving body.

When the prioritized passage moving body completely passes through the junction control section S, the interlock signal of the other moving body located in the third control section S3 is released to allow the moving body to start driving.

On the other hand, when the junction section-side central control device 400 cannot select any one of the first moving body 220 and the second moving body 211 as the prioritized passage moving body in the state in which the first moving body 220 and the second moving body 211 are located in the third control section S3 and each of the first moving body 220 and the second moving body 211 generates the interlock signal, the junction section-side central control device 400 transfers an alarm to a higher-level control device (not illustrated). When the alarm for the interlock state is transferred to the higher-level control device, a manager, for example, may select the prioritized passage moving body and take actions against the situation, and then reset the system, thus releasing the interlock.

According to the present embodiment, there are advantages in that the occurrence of simultaneous entry into the danger zone may be minimized by providing notification of driving between moving bodies, and in that, when simultaneous entry occurs, the intervention of the manager is minimized, thus enabling the driving control of the moving bodies in the junction control section S to be more promptly and stably performed.

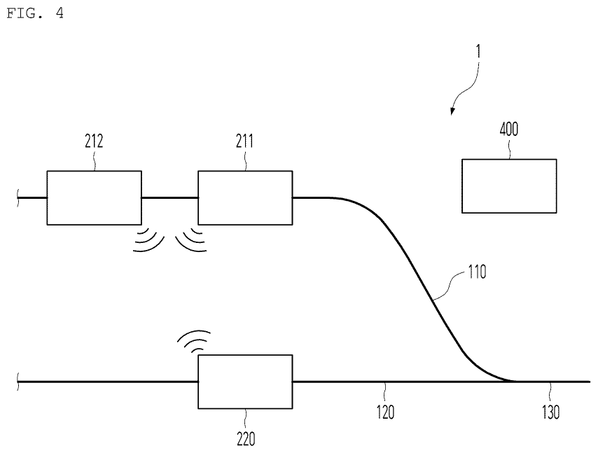

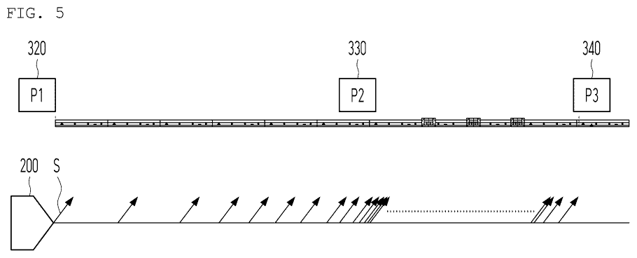

FIG. 4 is a diagram illustrating a process in which the vehicle control device of a moving body communicates with a junction section-side central control device in the location-based junction area passage control system of FIG. 1, and FIG. 5 is a diagram illustrating a process in which a vehicle control device transmits a driving state signal based on location information while a moving body passes through a junction area in the location-based junction area passage control system of FIG. 1.

Referring to FIGS. 4 and 5, moving bodies 211, 212, and 220 may communicate with each other, and each of them may obtain information about the locations and driving states of the others.

The first moving body 220 on a second rail 120 transmits a junction section-side communication signal to the moving bodies 211 and 212 located on a first rail 110 in a broadcast manner. Further, the moving bodies 211 and 212 located on the first rail 110 transmit a junction section-side communication signal to the moving body 220 located on the second rail 120 in a broadcast manner. Here, the junction section-side communication signal transmitted in the broadcast manner may also be received by a moving body on the same rail.

In an example, when the first rail-side first moving body 211 located on the first rail 110 first transmits a junction section-side communication signal corresponding to a driving state and enters a junction area J, the second rail-side first moving body 220 located on the second rail 120 generates an interlock signal in the case where a junction section-side communication signal corresponding to the driving state of the first rail-side first moving body 211 is received, thus stopping the driving thereof. In this case, the second rail-side first moving body 220 merely receives a wireless (RF) signal without transmitting an RF signal.

Here, when the first rail-side second moving body 212 located on the first rail 110 receives the junction section-side communication signal corresponding to the driving state of the first rail-side first moving body 211, the first rail-side second moving body 212 verifies that the first moving body 211 is located on the same rail, that is, the first rail 110, and continues driving. When the junction section-side communication signal of the first rail-side first moving body 211 cannot be received (i.e., when the first rail-side first moving body 211 completely passes through the junction area J and exits from the merge area S3), the first rail-side second moving body 212 transmits a junction section-side communication signal corresponding to a driving state based on locations. That is, the first rail-side second moving body 212 does not transmit an RF signal until the preceding first rail-side first moving body 211 has completely exited the junction area J.

According to the present embodiment, the present disclosure may perform a scheme in which only the moving body having passed through a collision danger zone transmits an RF signal based on the location, and may separate broadcast channels using multiple communication units, thus reducing the time during which a communication frequency band is occupied.

Meanwhile, the first rail-side second moving body 212 may maintain the distance to the first rail-side first moving body 211 or prevent a collision with the first rail-side first moving body 211 based on the sensing data of the distance measurement module installed on the first rail-side second moving body 212.

According to the present embodiment, when the number of devices that use wireless communication increases in a narrow space, communication performance may be deteriorated due to wireless (RF) interference between devices. In order to this, the present disclosure is advantageous in that communication stability and promptness may be secured while minimizing wireless (RF) interference by applying technology for varying a wireless (RF) transmission cycle based on the locations of the moving bodies 211, 212, and 220.

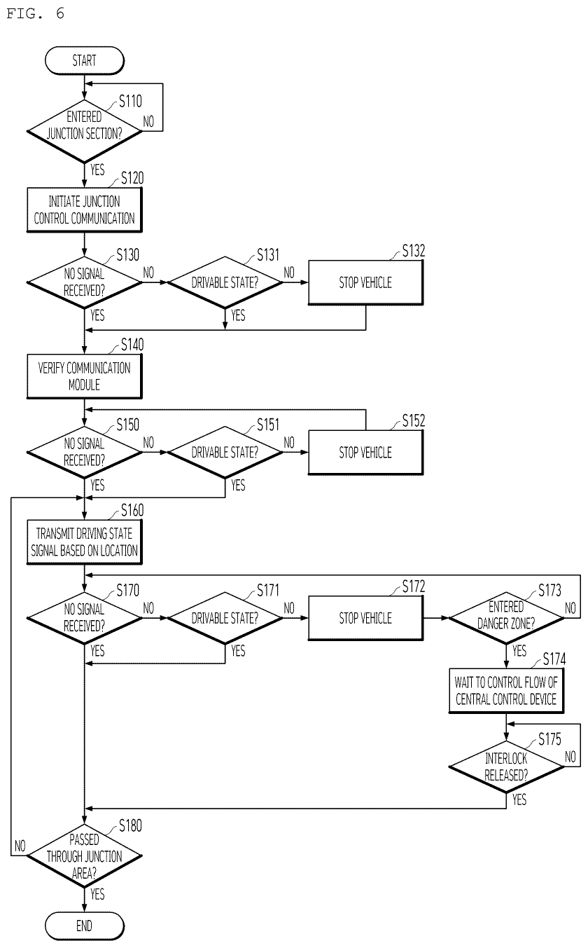

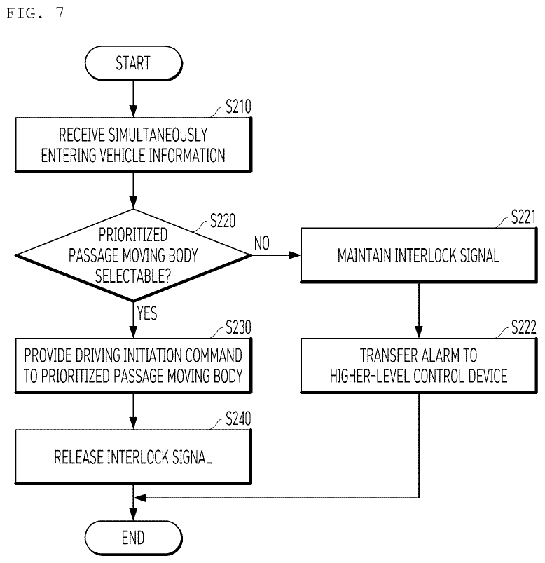

FIG. 6 is a flowchart illustrating a control process by the vehicle control device of the location-based junction area passage control system of FIG. 1, and FIG. 7 is a flowchart illustrating a control process by a junction section-side central control device when simultaneous entry occurs in a danger zone in the location-based junction area passage control system of FIG. 1.

First, referring to FIG. 6, a moving body junction area entry determination step S110 is performed to determine whether a moving body 210 or 220 traveling on any one of a first rail 110 and a second rail 120 has entered a junction area J in which the first rail 110 and the second rail 120 are merged with each other. Here, the vehicle control device 500 of each of the moving bodies 210 and 220 may determine whether the moving body 210 or 220 has entered the junction area J through identification tags installed on the first rail 110 and the second rail 120.

When the moving body 210 or 220 has entered the moving body junction area, a junction control communication mode initiation step S120 is performed to initiate the junction control communication mode of the moving body 210 or 220 in which the corresponding moving body 210 or 220 transmits and receives a junction section communication signal.

A first junction section communication signal reception/non-reception determination step S130 is performed to determine whether the moving body 210 or 220 in which the junction control communication mode has been initiated receives the junction section communication signal from the other moving body 210 or 220.

When a junction section communication signal is not received from the other moving body 210 or 220, a communication module verification step S140 is performed to verify the normal operation state of the communication module of the moving body 210 or 220 in which the junction control communication mode has been initiated.

When the communication module verification step S140 is terminated, a second junction section communication signal reception/non-reception determination step S150 is performed to determine whether the junction section communication signal of the other moving body 210 or 220 is received by the moving body 210 or 220 in which the communication module verification has been terminated.

When the junction section communication signal of the other moving body 210 or 220 is not received, a location-based driving state signal transmission step S160 is performed in which the moving body 210 or 220 transmits a junction section communication signal corresponding to a driving state. In this case, in the location-based driving state signal transmission step S160, the transmission cycle of the junction section communication signal may be variable. In an example, as the moving body 210 or 220 approaches a danger zone S3, a transmission cycle for merge point communication may become shorter.

A third junction section communication signal reception/non-reception determination step S170 is performed to determine whether the junction section communication signal of the other moving body 210 or 220 is received by the moving body 210 or 220 in which the transmission of the junction section communication signal corresponding to the driving state has been initiated.

Thereafter, whether the moving body 210 or 220 has passed through the junction area J is determined. When it is determined that the moving body 210 or 220 has passed through the junction area J, control may be terminated, whereas when it is determined that the moving body 210 or 220 has not passed through the junction area J, the location-based driving state signal transmission step S160 is performed.

On the other hand, in the first junction section communication signal reception/non-reception determination step S130, the second junction section communication signal reception/non-reception determination step S150, and the third junction section communication signal reception/non-reception determination step S170, when the junction section communication signal of the other moving body 210 or 220 is received, drivability determination steps S131, S151, and S171 of determining whether driving is possible are performed, respectively.

In each of the drivability determination steps S131, S151, and S171, (1) in the state in which the other moving body 210 or 220 is located on the same rail 110 or 120 or (2) when the verification for the communication module is performed in the other moving body, based on the junction section communication signal of the other moving body 210 or 220, the driving of the moving body 210 or 220 continues.

On the other hand, in each of the drivability determination steps S131, S151, and S171, when it is determined, based on the junction section communication signal of the other moving body 210 or 220, that the other moving body 210 or 220 is traveling while being located on the other rail 110 or 120, an interlock signal is transmitted to control the corresponding moving body to stop the driving thereof in step S132, S152, or S172.

Further, in the state in which the driving of the moving body 210 or 220 stops, whether the moving body 210 or 220 has entered the danger zone of the junction area J is determined in step S173. When it is determined that the moving body 210 or 220 has entered the danger zone, a central control device flow control waiting step S174 is performed in which the moving body 210 or 220 follows the flow control of the junction section-side central control device 400.

In the central control device flow control waiting step S174, the vehicle control device 500 of the moving body located in the danger zone transmits a junction section communication signal corresponding to a stopped state attributable to simultaneous entry.

Next, referring to FIG. 7, a control process by the junction section-side central control device 400 in the situation of simultaneous entry is illustrated.

First, a simultaneously entering vehicle information reception step S210 is performed in which the junction section-side central control device 400 receives junction section communication signals corresponding to the stopped state of the simultaneously entering moving bodies 210 and 220.

Then, a prioritized passage moving body selectability determination step S220 is performed in which the junction section-side central control device 400 selects a moving body to perform prioritized passage through the danger zone between the simultaneously entering moving bodies 210 and 220.

First, in the prioritized passage moving body selectability determination step S220, the junction section-side central control device 400 selects the moving body 210 or 220 with a shorter distance to the passage point of the junction area J or a shorter time to pass through the passage point, as a prioritized passage moving body, between the moving bodies 210 and 220, and transfers a driving initiation command to the selected prioritized passage moving body in step S230. The remaining moving body 210 or 220 other than the moving body 210 or 220 selected as the prioritized passage moving body still remains interlocked.

Furthermore, when the prioritized passage moving body has completely passed through the junction area J, the interlock signal for the other moving body 210 or 220 is released in step S240.

Meanwhile, in the prioritized passage moving body selectability determination step S220, when the junction section-side central control device 400 cannot select the moving body to perform prioritized passage, the interlock state of all moving bodies 210 and 220 is maintained in step S221. A higher-level control device alarm step S222 is performed in which the junction section-side central control device 400 transfers an alarm to a higher-level control device (not illustrated), and control is terminated.

Referring back to FIG. 6, when the interlock signal is released in step S240, the driving of the moving body 210 or 220, which has stopped in the danger zone, that is, the third control section S3, is initiated. When it is determined that the moving body 210 or 220 has completely passed through the junction area J in step S180, control is terminated.

According to proposed embodiments, a simple wireless communication configuration that enables driving control and interlock control in a junction section may be provided, without requiring a complex setup such as installing power line communication lines for communication on the tracks of a junction section.

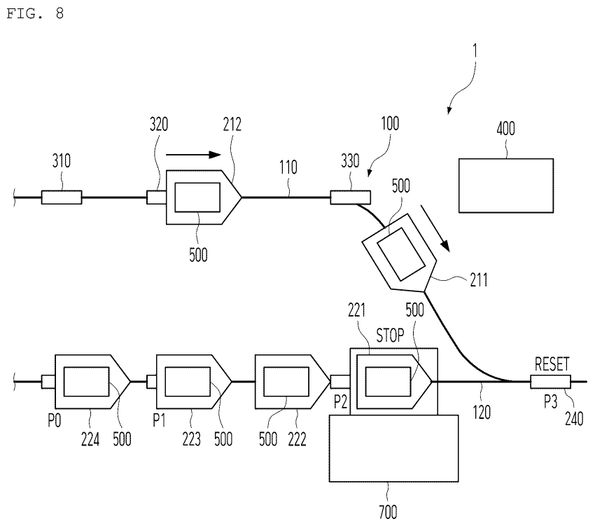

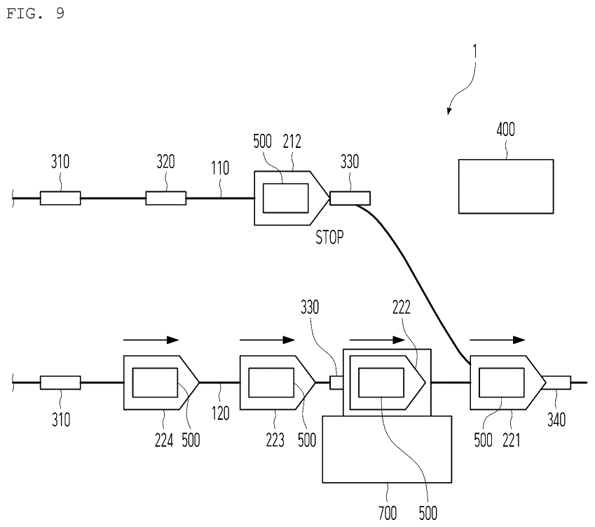

FIGS. 8 and 9 are diagrams illustrating a process of controlling junction and passage of a moving body in a location-based junction area passage control system according to another embodiment of the present disclosure.

The present embodiment differs only in a configuration in which a loading/unloading platform 700 is placed in the danger zone, and is substantially identical in other components to the junction area passage control system and the junction area passage control method illustrated in FIGS. 1 to 7. Therefore, the following description will be made based on the characteristic features of the present embodiment.

First, referring to FIG. 8, in the danger zone of a second rail 120, that is, in a third control section S3, a loading/unloading platform 700 is placed to allow goods involved in a semiconductor manufacturing process to be either loaded onto a moving body 221 or unloaded from the moving body 221.

Also, states distinguished in communication signal type information of junction section communication signals may further include an operational state indicating the state in which the moving body is performing a loading/unloading operation.

When the first moving body 221 of the second rail 120 performs a loading/unloading operation in the loading/unloading platform 700, the vehicle control device 500 of the second rail-side first moving body 221 transmits a junction section communication signal corresponding to the operational state.

The vehicle control device 500 of the first rail-side moving body 211 or 212, which travels on the first rail 110 that is another rail, receives the junction section communication signal corresponding to the operational state, checks the “remaining distance to a collision zone” between the stop location of the second rail-side first moving body 221 and the junction section, and allows the first rail-side moving body 211 or 212 to continue the driving thereof in the third control section S3 without stopping if passing is enabled. That is, although the second rail-side first moving body 221 is located in the third control section S3, the moving body 211 or 212 may travel on the first rail 110 without being controlled to be separately interlocked until the operation of the second rail-side first moving body 221 is terminated.

The vehicle control device 500 of the first rail-side moving body 211 or 212 checks the “remaining distance to the collision zone” between the stop location of the second rail-side first moving body 221 and the junction section. When passing is impossible, the first rail-side moving body 211 or 212 stops and waits.

Here, the second rail-side moving bodies 222, 223, and 224 following the second rail-side first moving body 221 may wait in a stopped state in an area behind the second rail-side first moving body 221, that is, within a range from the first control section S1 to the second control section S2.

Next, referring to FIG. 9, when the loading/unloading operation of the first moving body 221 of the second rail 120 is terminated in the loading/unloading platform located in the third control section S3, the vehicle control device 500 of the second rail-side first moving body 221 on which the loading/unloading operation is terminated determines whether a junction section communication signal corresponding to the driving state of the vehicle control device 500 of the first rail-side moving body 212 traveling on the first rail 110 that is the other rail is received. Further, when the junction section communication signal corresponding to the driving state of the first rail-side moving body 212 is not received, the vehicle control device 500 of the second rail-side first moving body 221 transmits the junction section communication signal corresponding to the driving state, and resumes the driving of the second rail-side first moving body 221.

In the present embodiment, although a configuration in which the operational state of other moving bodies can be detected by signal transmission/reception between moving bodies has been described, a configuration in which the moving body in the operational state transmits the junction section communication signal corresponding to the operational state to the junction section-side central control device 400 and in which the junction section-side central control device 400 broadcasts a control signal to the moving bodies to control the moving bodies is also be included in the embodiment of the present disclosure.

According to the present embodiment, there are advantages in that, when another operation is performed in the danger zone of the junction area J, the unnecessary occurrence of interlock by the moving body which performs the corresponding operation may be suppressed, and the transportation efficiency of moving bodies may be increased based on such suppression.

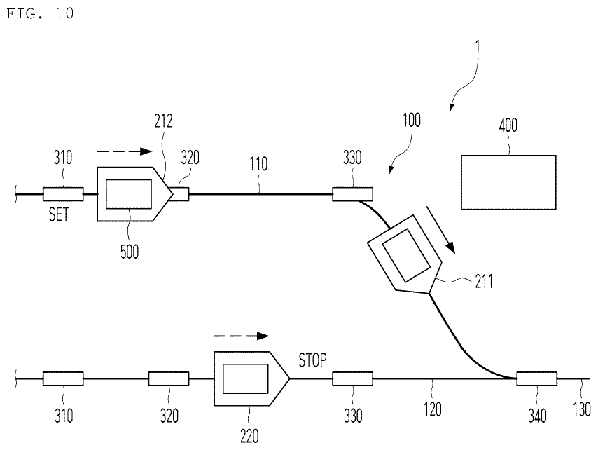

FIG. 10 is a diagram illustrating a process of controlling junction and passage of a moving body in a location-based junction area passage control system according to a further embodiment of the present disclosure.

The present embodiment differs only in a configuration in which the junction section-side central control device 400 performs control prior to the vehicle control device 500, and is substantially identical in other configurations to the junction area passage control system and the junction area passage control method illustrated in FIGS. 1 to 7. Therefore, the following description will be made based on the characteristic features of the present embodiment.

The junction section-side central control device 400 of the location-based junction area passage control system 1 according to the present embodiment monitors the locations and movement states of a plurality of moving bodies 211, 212 and 220 in a junction area J, based on junction section communication signals transmitted from the plurality of moving bodies 211, 212, and 220, and selects a moving body to perform prioritized passage through the danger zone of the junction area J from among the moving bodies 211, 212, and 220. Further, the junction section-side central control device 400 transmits a junction section communication signal for allowing the selected moving body 211, 212, or 220 to perform prioritized passage to the moving bodies 211, 212, and 220. When the moving body to perform prioritized passage is selected, the junction section-side central control device 400 may select the prioritized passage moving body based on the waiting times, junction area passage times, etc. of the moving bodies.

In detail, the junction section-side central control device 400 may select the moving body to perform prioritized passage in the third control section S3 based on the location information of the moving bodies, and controls the remaining moving bodies located in the junction area J, other than the moving body to perform prioritized passage, to prevent them from entering the third control section S3.

In the proposed embodiment, the junction section-side central control device 400 of the junction area passage control system 1 performs control of junction and passage of the moving bodies 211, 212, and 220, thus obtaining an advantage in that more stable junction area passage control is enabled.

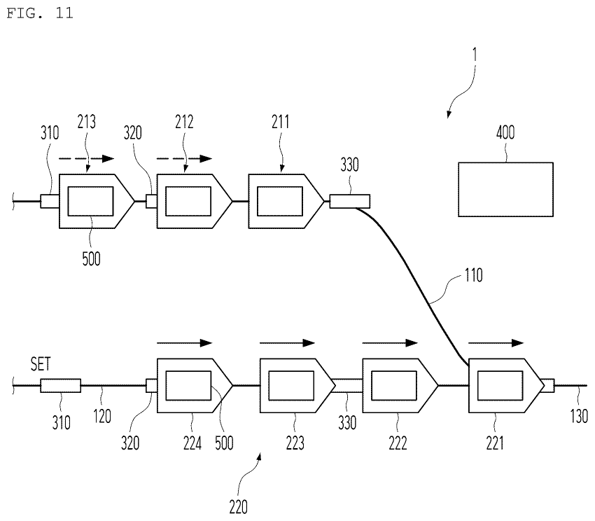

FIG. 11 is a diagram illustrating a process of controlling junction and passage of a moving body in a location-based junction area passage control system according to yet another embodiment of the present disclosure.

The present embodiment differs only in a configuration in which a plurality of moving bodies traveling on preset rails in a junction area passage control system 1 are clustered to allow a plurality of clustered moving bodies to sequentially pass through a junction section, and is substantially identical in other configurations to the junction area passage control system and the junction area passage control method illustrated in FIGS. 1 to 10. Therefore, the following description will be made based on the characteristic features of the present embodiment.

Referring to FIG. 11, when at least one additional moving body is located in a junction area including the same rail as a moving body 221 to perform prioritized passage and on a rail different from that of the moving body 221, the junction section-side central control device 400 calculates (1) a sequential prioritized passage time required for the moving bodies located on different rails 110 and 120 to sequentially perform prioritized passage, and (2) a clustered prioritized passage time required for moving bodies located on the same rail as the moving body 221 which performs prioritized passage to consecutively perform prioritized passage.

Further, when the clustered priority passage time is shorter than the sequential prioritized passage time, clustered prioritized passage control is performed such that a plurality of moving bodies 222, 223, and 224 on the rail on which the moving body 221 which performs prioritized passage is located are selected as a prioritized passage cluster to allow the selected cluster to perform prioritized passage. Moving bodies 211, 212, and 213 on the remaining rail 110, other than the moving bodies on which the clustered prioritized passage control is performed, are controlled to prevent them from entering the third control section S3.

The moving bodies 221, 222, 223, and 224 included in the prioritized passage cluster may be within a junction communication range between the moving bodies and the junction section-side central control device 400. The junction communication range may be formed to be equal to or larger than the junction area J of the rails.

In the present embodiment, for example, a configuration is described in which the clustered prioritized passage time of the second rail-side moving bodies 221, 222, 223, and 224 located on the second rail 120 is calculated to be shorter than the sequential prioritized passage time during which the first rail-side moving bodies 211, 212, and 213 and the second rail-side moving bodies 221, 222, 223, and 224 alternately pass through the junction section, and thus the second rail-side moving bodies 221, 222, 223, and 224 are subjected to the clustered prioritized passage control.

According to the proposed embodiment, there is an advantage in that, during the driving of the clustered moving bodies, the driving of the moving bodies is performed in the junction area without acceleration or deceleration of the moving bodies, thus improving the overall transportation efficiency.

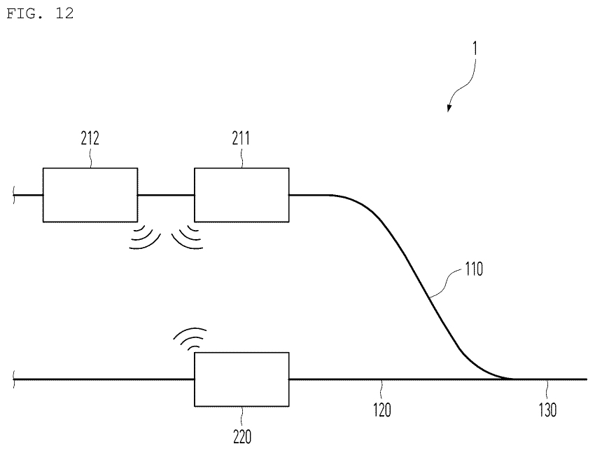

FIG. 12 is a diagram illustrating a location-based junction area passage control system according to still another embodiment of the present disclosure.

The present embodiment differs only in a configuration in which control is performed between the vehicle control devices 500 without intervention of the junction section-side central control device 400, and is substantially identical in other configurations to the junction area passage control system and the junction area passage control method illustrated in FIGS. 1 to 7. Therefore, the following description will be made based on the characteristic features of the present embodiment.

Referring to FIG. 12, a vehicle control device installed in each of moving bodies 211, 212, and 220 of a junction area passage control system 1 according to the present embodiment transmits/receives junction section communication signals to/from a vehicle control device installed in another moving body 211, 212, or 220, and sets entry priority of the moving bodies into a danger zone based on the mutual locations thereof.

Meanwhile, when at least two of the moving bodies 211, 212, and 220 simultaneously enter the danger zone, the moving bodies that have simultaneously entered the danger zone may stop by transmitting a junction section communication signal corresponding to a stopped state. The stopped moving bodies may choose a representative moving body for selecting a prioritized passage moving body in the danger zone. The representative moving body selects the prioritized passage moving body by receiving junction section communication signals from the other moving bodies.

When the representative moving body selects the prioritized passage moving body, the representative moving body selects the prioritized passage moving body based on the distances to the point at which the rails are merged. The prioritized passage moving body transmits a junction section communication signal corresponding to a driving state, and then passes through the danger zone.

Meanwhile, when the prioritized passage moving body cannot be selected, the representative moving body transmits an alarm signal against simultaneous entry and waits for a system manager to take actions.

According to proposed embodiments, a simple wireless communication configuration that enables driving control and interlock control in a junction section may be provided, without requiring a complex setup such as installing power line communication lines for communication on the tracks of a junction section.

Further, the configuration of a junction section driving control system may be simplified, and facility costs can be reduced.

Furthermore, compared to conventional optical communication, power line communication, or communication using power line communication lines, there is no need to install equipment having a complex configuration on tracks, and it is possible to perform collision prevention and driving control in a junction section through only wireless communication based on a simple configuration.

When the number of devices that use wireless (RF) communication increases in a narrow space, communication performance may be deteriorated due to wireless (RF) interference between the devices. In order to prevent this, communication stability and promptness may be secured while minimizing wireless (RF) interference by applying technology for varying a wireless (RF) transmission cycle based on the location of a transport vehicle.

In addition, a self-interlock mechanism that operates due to malfunctioning may be configured by adding a self-diagnosis function to a wireless communication device.

In a scheme configured in the present patent, even if a central controller is removed, the present disclosure may be operated as a junction area passage control system, and the function of the central controller may be determined even in a communication device between vehicles.

Further, by means of only wireless communication between vehicles, a vehicle to enter a junction driving section first may be selected.

Furthermore, by measuring the movement distance of a transport vehicle in real-time, the absolute position of the vehicle may be recognized. Also, even in the cases where an emergency stop occurs due to simultaneous entry of vehicles, driving priority may be determined and a driving resumption sequence may be executed based on the precise positional relationship between the vehicles.

A wireless (RF) communication module establishes a mutual link with a central controller or between vehicles in a junction section, and links with the communication module of a load port when approaching manufacturing equipment, thereby improving the operational efficiency of communication devices.

Technology for recognizing the absolute position of a transport vehicle may enhance the precision of operational control of overall Overhead Hoist Transport (OHT) driving, not only in traveling in a junction section but also in improving the stopping precision of the vehicle during carrier loading/unloading to/from manufacturing equipment.

In the above description, although embodiments of the present disclosure have been described, it is apparent that the present disclosure is not limited thereto and various modifications and substitutions are possible within the scope of the claims, detailed description, and drawings of the present disclosure, and that these modifications and substitutions also fall within the scope of the present disclosure.

What is claimed is:

1. A junction area passage control system based on a location of moving body using wireless communication on a rail, the rail including a junction section formed by merging of two or more rails, the junction area passage control system comprising:
a vehicle control device installed on each of a plurality of moving bodies, and including a communication module for wireless communication between the moving bodies and a control unit configured to control driving of a corresponding moving body; and
a junction section-side central control device including a communication module configured to perform wireless communication with the vehicle control device, the junction section-side central control device being configured to receive information about locations and movement states of the plurality of moving bodies in the junction section, monitor driving situations of the plurality of moving bodies traveling in the junction section, and determine entry priority of the plurality of moving bodies,
wherein, in a normal state, control of the corresponding moving body by the vehicle control device is performed, and in an emergency state, control by the junction section-side central control device is prioritized over the control by the vehicle control device, and
wherein the emergency state is a case where the moving bodies on the respective rails simultaneously enter a junction driving zone set in the junction section.

2. The junction area passage control system of claim 1, wherein the junction section includes a first control section in which junction control communication initiation of transmitting and receiving a junction section communication signal and verification for the communication module of the vehicle control device are performed, a second control section that follows the first control section and in which location-based movement control of the corresponding moving body is performed, and a third control section that follows the second control section and corresponds to the junction driving zone.

3. The junction area passage control system of claim 2, wherein the communication module of the vehicle control device comprises:
a first communication unit configured to receive a junction section communication signal of a communication module of another moving body on an identical rail among rails in the junction section and transmit a junction section communication signal to a communication module of an additional moving body on a rail different from the corresponding rail;
a second communication unit configured to receive the junction section communication signal of the communication module of the additional moving body on the different rail, receive the junction section communication signal of the first communication unit, and then determine a normal communication state of the communication module of the vehicle control device;
a third communication unit configured to receive the junction section communication signal of the communication module of the additional moving body on the different rail; and
a fourth communication unit configured to enable communication with the communication module of the junction section-side central control device.

4. The junction area passage control system of claim 2, further comprising:
a track indication device attached to a rail body of each of the rails,
wherein each of the moving bodies further comprises a movement distance measurement module configured to measure a rail movement distance of a corresponding moving body, and an indication device recognition module capable of recognizing the track indication device,
wherein the track indication device comprises a first track indication device,
wherein the movement distance measurement module comprises an optical sensor or a camera module,
wherein the first track indication device is arranged at a start point of the first control section,
wherein, when the indication device recognition module of the moving body recognizes the first track indication device, the moving body is determined to have entered the first control section, and
wherein the track indication device is an optical tag that is capable of being optically recognized.

5. The junction area passage control system of claim 4, wherein:
the track indication device further comprises a second track indication device and a third track indication device arranged at locations different from that of the first track indication device,
when the moving body recognizes the second track indication device, the moving body is determined to have entered the second control section, and
when the moving body recognizes the third track indication device, the moving body is determined to have entered the third control section.

6. The junction area passage control system of claim 4, wherein:
when the moving body is determined to have entered the first control section to perform verification for the communication module in the first control section and then the verification for the communication module is completed, location-based movement control in the second control section is performed, and
when the moving body is moved by a predetermined distance in a state in which the moving body has entered the second control section, the moving body is determined to have entered the third control section.

7. The junction area passage control system of claim 4, wherein:
when a signal received through the communication module of the moving body that has entered the second control section of the junction section is (1) a junction section communication signal corresponding to a driving state of another moving body located on a rail identical to the rail on which the moving body is traveling, or (2) a junction section communication signal corresponding to verification for a communication module of an additional moving body on the identical rail or a rail different from the rail, the moving body continues driving thereof, and
when the signal received through the communication module of the moving body that has entered the second control section of the junction section is a junction section communication signal corresponding to a driving state of the additional moving body located on the rail different from the rail on which the moving body is traveling, the moving body stops driving thereof by transmitting an interlock signal, and
when a signal received through the communication module of the moving body that has entered the third control section of the junction section is (1) a junction section communication signal corresponding to a driving state of additional moving bodies on the rail different from the rail on which the moving body is traveling, all of the moving body on the rail and the additional moving bodies on the different rail stop driving thereof by transmitting interlock signals, wherein at least one of the moving body and the additional moving bodies transmits a junction section communication signal corresponding to a stopped state to the junction section-side central control device.

8. The junction area passage control system of claim 7, wherein, when the junction section communication signal corresponding to the stopped state is received, the junction section-side central control device is configured to select, as a prioritized passage moving body, a moving body with a shorter distance to a passage point of the junction area or with a shorter passage time to pass through the passage point from among moving bodies that have entered the third control section, and to transmit a junction section-side central control signal for releasing an interlock signal for the prioritized passage moving body to resume driving of the prioritized passage moving body.

9. The junction area passage control system of claim 2, wherein transmission speed of the junction section communication signal transmitted from each moving body increases in an order in which the moving body is located in the first control section, the second control section, and the third control section, and transmission of the junction section communication signal is terminated when the moving body has passed through the junction area.

10. The junction area passage control system of claim 2, wherein transmission speed of the junction section communication signal transmitted from each moving body increases as a speed of the moving body becomes higher.

11. The junction area passage control system of claim 2, wherein:
the junction section communication signal further include an operational state indicating a state in which each moving body performs a loading/unloading operation,
a loading/unloading platform in which the moving body performs the loading/unloading operation is arranged in the third control section of at least one of a plurality of rails, and
when the moving body performs the loading/unloading operation in the loading/unloading platform, the vehicle control device of the moving body transmits a junction section communication signal corresponding to the operational state, and a vehicle control device of an additional moving body traveling on a rail different from that of the moving body receives the junction section communication signal corresponding to the operational state and allows the additional moving body to continue driving in the third control section.

12. The junction area passage control system of claim 11, wherein, when the loading/unloading operation of the moving body is terminated in the junction section, the vehicle control device of the moving body on which the loading/unloading operation is terminated is configured to determine whether a junction section communication signal corresponding to a driving state of the vehicle control device of the additional moving body traveling on the different rail is received, and to transmit the junction section communication signal corresponding to the driving state and resume driving of the corresponding moving body when the junction section communication signal corresponding to the driving state is not received from the additional moving body.

13. The junction area passage control system of claim 4, wherein the junction section-side central control device monitors the locations and the movement states of the plurality of moving bodies in the junction section based on junction section communication signals transmitted from the plurality of moving bodies, selects a moving body to perform prioritized passage in the third control section from among the plurality of moving bodies, and transmits a junction section communication signal for allowing the selected moving body to perform prioritized passage.

14. The junction area passage control system of claim 13, wherein the junction section-side central control device controls moving bodies located in the junction area, other than the moving body to perform prioritized passage, to prevent the moving bodies from entering the third control section.

15. The junction area passage control system of claim 14, wherein, when one or more additional moving bodies are located in a junction area including rails identical to and different from that of the moving body to perform prioritized passage, the junction section-side central control device calculates (1) a sequential prioritized passage time required for moving bodies located on different rails to sequentially perform prioritized passage, and (2) a clustered prioritized passage time required for moving bodies located on the identical rail on which the moving body to perform the prioritized passage is located to consecutively perform prioritized passage,
when the clustered prioritized passage time is shorter than the sequential prioritized passage time, clustered prioritized passage control is performed such that the plurality of moving bodies on the identical rail on which the moving body to perform prioritized passage is located are selected as a prioritized passage cluster to perform prioritized passage,
moving bodies on a remaining rail, other than the moving bodies on which the clustered prioritized passage control is performed, are controlled to prevent the moving bodies from entering the third control section, and
the moving bodies included in the prioritized passage cluster are within a junction communication range between the moving bodies and the junction section-side central control device, wherein the junction communication range is equal to or greater than the junction area of the rail.

16. A junction area passage control method using a location-based junction area passage control system based on a location of a moving body using wireless communication on a rail including a first rail, a second rail forming a route different from that of the first rail, and a junction rail formed by merging of the first rail and the second rail, wherein the location-based junction area passage control system comprises a vehicle control device installed on each of a plurality of moving bodies and including a communication module for wireless communication between the moving bodies and a control unit configured to control driving of each moving body, the junction area passage control method comprising:
a moving body junction area entry determination step of determining whether a moving body traveling on any one of the first rail and the second rail has entered a junction area in which the first rail and the second rail are merged;
a junction control communication mode initiation step of, when the moving body has entered the junction area, initiating a junction control communication mode of the moving body in which a junction area communication signal is transmitted and received;
a first junction section communication signal reception/non-reception determination step of determining whether a junction section communication signal of an additional moving body is received by the moving body in which the junction control communication mode has been initiated;
a communication module verification step of checking a normal operation state of a communication module of the moving body on which the junction control communication mode has been initiated; and
when the communication module verification step is terminated, a location-based driving state signal transmission step of transmitting, by the moving body, a junction section communication signal corresponding to a driving state.

17. The junction area passage control method of claim 16, further comprising:
a second junction section communication signal reception/non-reception determination step of determining whether the junction section communication signal of the additional moving body is received by the moving body on which verification for a communication module is terminated; and
a third junction section communication signal reception/non-reception determination step of determining whether the junction section communication signal of the additional moving body is received by the moving body in which transmission of the junction section communication signal corresponding to the driving state has been initiated.

18. The junction area passage control method of claim 17, wherein:
in the first junction section communication signal reception/non-reception determination step, the second junction section communication signal reception/non-reception determination step, and the third junction section communication signal reception/non-reception determination step, when the junction section communication signal of the additional moving body is received, a drivability determination step of determining whether driving is possible is performed,
in the drivability determination step, driving of the moving body continues either in a state in which the additional moving body is located on the identical rail or when the verification for the communication module is performed on the additional moving body, based on the junction section communication signal of the additional moving body, and
in the drivability determination step, driving of the moving body stops when it is determined, based on the junction section communication signal of the additional moving body, that the additional moving body is traveling while being located on the different rail.

19. The junction area passage control method of claim 18, further comprising:
a step of determining whether the moving body has entered a danger zone of the junction area in a state in which the driving of the moving body stops, and
a central control device flow control waiting step of, when the moving body has entered the danger zone, allowing the moving body to follow flow control of a junction section-side central control device.

20. The junction area passage control method of claim 19, wherein, in the central control device flow control waiting step, a vehicle control device of the moving body located in the danger zone transmits a junction section communication signal corresponding to a stopped state.

21. The junction area passage control method of claim 19, wherein the central control device flow control waiting step comprises:
a simultaneously entering vehicle information reception step of allowing the junction section-side central control device to receive junction section communication signals of moving bodies simultaneously entering the danger zone; and
a prioritized passage moving body selectability determination step of allowing the junction section-side central control device to select a moving body to perform prioritized passage through the danger zone from among the simultaneously entering moving bodies,
wherein, in the prioritized passage moving body selectability determination step, the junction section-side central control device selects, as a prioritized passage moving body, a moving body with a shorter distance to a passage point of the junction area or a shorter passage time to the passage point from among moving bodies that have simultaneously entered the danger zone, and
wherein the prioritized passage moving body selectability determination step comprises, when the junction section-side central control device cannot select the moving body to perform prioritized passage, a higher-level control device alarm step of allowing the junction section-side central control device to transfer an alarm to a higher-level control device.

22. The junction area passage control method of claim 16, wherein:
in each of the first rail and the second rail, a junction control section is established, and
the junction control section includes a first control section in which junction control communication initiation of transmitting and receiving a junction section communication signal and verification for the communication module of the vehicle control device are performed, a second control section that follows the first control section and in which location-based movement control of the corresponding moving body is performed, and a third control section that follows the second control section and corresponds to a junction driving zone.

23. The junction area passage control method of claim 22, wherein transmission speed of the junction section communication signal transmitted from each moving body increases in an order in which the moving body is located in the first control section, the second control section, and the third control section, and transmission of the junction section communication signal is terminated when the moving body has passed through the junction area.

24. The junction area passage control method of claim 16, wherein transmission speed of the junction section communication signal transmitted from each moving body increases as a speed of the moving body becomes higher.

25. The junction area passage control method of claim 16, wherein:
the communication module of the vehicle control device comprises a plurality of communication units, and
in the communication module verification step, in a state in which a first communication unit, among the communication units of the moving body, transmits a junction section communication signal corresponding to a communication module verification state, (1) when a second communication unit different from the first communication unit, among the communication units of a moving body identical to the moving body, receives the junction section communication signal transmitted from the first communication unit, the communication module of the moving body is determined to be in a normal state, and (2) when the second communication unit of the identical moving body cannot receive the junction section communication signal transmitted from the first communication unit, the communication module is determined to be in an abnormal state, and
when the communication module is determined to be in an abnormal state, the vehicle control device stops by transmitting an interlock signal, and transfers a communication module error signal indicating the abnormal state of the communication module to a junction section-side central control device.

26. A junction area passage control system based on a location of a moving body using wireless communication on a rail, the rail including a junction section formed by merging of two or more rails, the junction area passage control system comprising:
a vehicle control device installed on each of moving bodies and including a communication module for wireless communication between the moving bodies and a control unit configured to control driving of a corresponding moving body,
wherein the moving bodies are provided in plurality, and
wherein the vehicle control device installed on any one of the moving bodies transmits and receives a junction section communication signal to/from a vehicle control device installed on another moving body, and is configured to set entry priority of the moving bodies into a danger zone based on mutual locations of the moving bodies.

27. The junction area passage control system of claim 26, wherein:
when at least two of the moving bodies simultaneously enter the danger zone, the moving bodies that simultaneously enter the danger zone stop while transmitting a junction section communication signal corresponding to a stopped state, the stopped moving bodies choose a representative moving body for selecting a prioritized passage moving body in the danger zone, and the representative moving body receives junction section communication signals of other moving bodies to select a prioritized passage moving body, and
when the representative moving body selects the prioritized passage moving body, the representative moving body selects the prioritized passage moving body based on distances to a point at which the rails are merged.
